(19) United States
(12) Patent Application Publication
(10) Pub. No.: US 2012/0015497 A1
(43) Pub. Date: Jan. 19, 2012

(54) Preparing a Surface of a Sapphire Substrate for Fabricating Heterostructures

(76) Inventors: Gweltaz Gaudin, Grenoble (FR); Mark Kennard, Crolles (FR); Matteo Piccin, Meylan (FR); Ionut Radu, Crolles (FR); Alexandre Vaufredaz, La Murette (FR)

(21) Appl. No.: 13/130,239

(22) PCT Filed: Nov. 16, 2009
(86) PCT No.: PCT/EP2009/065202

§ 371 Date: Sep. 30, 2011

(30) Foreign Application Priority Data
Nov. 19, 2008 (FR) 0857854

(51) Int. Cl. H01L 21/762

(52) U.S. Cl. 438/455; 257/E21.567

(57) ABSTRACT

A method of fabricating a heterostructure comprising at least a first substrate (120) made of sapphire and a second substrate (110) made of a material having a coefficient of thermal expansion that is different from that of the first substrate. The method includes a step (S6) of molecular bonding the second substrate (110) on the first substrate (120) made of sapphire. The method also includes, prior to bonding the two substrates together, a step (S1) of stoving the first substrate (120) at a temperature that lies in the range 100° C. to 500° C.

### RELATED APPLICATIONS

This is a U.S. National Phase Application under 35 USC 371 of International Application PCT/EP2009/065202 filed on Nov. 16, 2009.

This Application claims the priority of French Application No. 08/57854 filed Nov. 19, 2008, the entire content of which is hereby incorporated by reference.

### FIELD OF THE INVENTION

The present invention relates to fabricating heterostructures formed by bonding at least one substrate made of a semiconductor material such as silicon on a substrate made of sapphire (Al₂O₃). The invention applies in particular to fabricating silicon-on-sapphire (SOS) type structures.

### BACKGROUND OF THE INVENTION

Heterostructures comprising a layer of silicon on a sapphire substrate present particular advantages. SOS structures enable high frequency devices to be made that present low energy consumption. The use of sapphire substrates also makes it possible to achieve very good heat dissipation, better than that obtained for example with silicon substrates.

SOS structures were initially made by epitaxially growing a layer of silicon on a sapphire substrate. Nevertheless, with that technique, it is difficult to obtain layers or films of silicon that present a low density of crystal defects, given the large difference between the lattice parameters and the coefficients of thermal expansion of the two materials.

In another technique, SOS structures are made by assembling a layer of silicon on a sapphire substrate. In well-known manner, use is made of molecular bonding (also known as “direct wafer bonding” or “fusion bonding”) which is a technique that enables two substrates to be bonded together providing they present surfaces that are perfectly plane (“mirror polish”), and without using an intermediate adhesive (glue, solder, etc.). Bonding is typically initiated by local application of a small amount of pressure to the two substrates that have been put into intimate contact. A bonding wave then propagates over the entire extent of the substrate in a few seconds.

In addition, in order to enable good molecular bonding to be achieved between the substrates, their bonding faces need to present a very low density of contaminants. These contaminants, which may come from the material itself or from prior treatment such as chemical-mechanical-polishing (CMP), are essentially of particulate, metallic, and organic origin.

Consequently, it is well known to proceed with cleaning of the polished bonding surfaces of each of the substrates. With sapphire, the cleaning generally consists in treating the substrate with a chemical cleaning agent of the RCA type.

Furthermore, in order to obtain bonding energy between the two substrates that is sufficient to be able in particular to withstand the subsequent steps of polishing, chemical attack, etc., the two substrates as bonded together in this way are subjected to heat treatment known as a bonding reinforcing anneal or as a stabilizing anneal. The anneal is generally performed at high temperatures of about 700° C. to 800° C.

Nevertheless, with a heterostructure made by bonding a silicon substrate on a sapphire substrate, such temperatures cannot be used because of the large difference between the coefficients of thermal expansion of silicon and of sapphire (3.6×10⁻⁶/° C. for silicon and 5×10⁻⁶/° C. for sapphire). If a silicon heterostructure on sapphire is raised after bonding to the temperatures that are usually used for reinforcing the bonding interface, high thermomechanical stresses arise in the structure, thereby leading to the appearance and propagation of cracks in the silicon.

Consequently, in order to preserve the integrity of the silicon, anneals for reinforcing the bonding interface can be performed only at temperatures that are relatively low (<300° C.) compared with those usually used. This temperature limitation does not enable a high level of bonding energy to be obtained between the silicon substrate and the sapphire substrate.

Methods of bonding silicon-on-sapphire are described in the following documents:

G. P. Imthurn, G. A. Garcia, H. W. Walker, and L. Forbes, “Bonded silicon-on-sapphire wafers and devices”, J. Appl. Phys., 72(6), Sep. 15, 1992, pp. 2526-2527;

U.S. Pat. No. 5,441,591;

Takao Abe et al., “Dislocation-free silicon-on-sapphire by wafer bonding”, January 1994, Jpn. J. Appl. Phys., Vol. 33, pp. 514-518;

Kopperschmidt et al., “High bond energy and thermomechanical stress in silicon-on-sapphire wafer bonding”, Appl. Phys. Lett., 70(22), p. 2972, 1977.

### SUMMARY OF THE INVENTION

One of the objects of the invention is to remedy the above-mentioned drawbacks by proposing a solution that enables a heterostructure to be obtained by bonding, on a sapphire substrate, another substrate having a coefficient of thermal expansion that is different from that of sapphire, and to do so while obtaining good bonding energy between the substrates and while limiting the appearance of defects after bonding and while limiting treatments after bonding.

To this end, one aspect of the present invention relates to a method of fabricating a heterostructure comprising at least a first substrate made of sapphire and a second substrate made of a material having a coefficient of thermal expansion that is different from that of the first substrate, the method including a step of molecular bonding the second substrate on the first substrate made of sapphire, in which method, prior to bonding the two substrates together, a step is performed of stoving the first substrate at a temperature lying in the range 100° C. to 500° C. When the stoving step is performed at a temperature of 100° C., the duration of the stoving step is then at least 1 hour (h).

In unexpected manner, and as explained below in detail, such stoving of the sapphire substrate prior to bonding serves to improve significantly the energy and the quality of the bonding compared with bonding performed without the prior stoving step.

In an aspect of the invention, the stoving step is performed at a temperature of about 200° C. for a duration of about 2 h.

In another aspect of the invention, the quality of the bonding, and in particular the bonding energy, may be further improved by activating the bonding surface(s) of one or both substrates by means of plasma treatment.

To activate the bonding surface of the first substrate made of sapphire, the plasma is used at a mean power density that is preferably less than or equal to 1 watt per square centimeter (W/cm²). The plasma is also preferably a plasma based on oxygen.

According to an embodiment of the invention, the method further includes, prior to bonding the two substrates together, forming an oxide layer on the bonding surface of the second substrate.

Molecular bonding between the first and second substrate is preferably performed at ambient temperature.

After the two substrates have been bonded together, the method may further include a step of performing a bonding stabilizing anneal at a temperature of less than 300° C. This limit on the temperature of the stabilizing anneal serves to avoid excessive stresses arising in the structure because of the difference between the coefficients of thermal expansion of the two substrates. In spite of temperature being limited in this way, the stoving step of the invention makes it possible to obtain good bonding energy.

The second substrate may in particular be constituted by a layer of silicon or by a silicon-on-insulator (SOI) structure.

### BRIEF DESCRIPTION OF THE FIGURES

Other characteristics and advantages of the invention appear from the following description of particular implementations of the invention given as non-limiting examples, with reference to the accompanying drawings, in which:

FIG. 1 is a chart showing bonding energy values obtained as a function of how the sapphire substrate surface is prepared and as a function of the stabilization anneal temperature;

FIG. 2 is a chart showing the different lengths of ring obtained as a function of the mean power density of the plasma used for activating the bonding surface of the sapphire substrate;

FIGS. 3A to 3F are diagrammatic views showing the fabrication of a heterostructure by implementing a method of the invention;

FIG. 4 is a flow chart of the steps implemented while fabricating the three-dimensional structure shown in FIGS. 3A to 3F; and

FIG. 5A shows an SOS type heterostructure in which the bonding surface of the sapphire support substrate has been prepared in accordance with the prior art, while FIG. 5B shows an SOS type heterostructure with the bonding surface of the sapphire support substrate prepared in accordance with an implementation of the method of the invention.

### DETAILED DESCRIPTION OF IMPLEMENTATIONS OF THE INVENTION

The present invention applies in general to molecular bonding between a first substrate made of sapphire and a second substrate made of some other material that presents a different coefficient of thermal expansion, such as in particular: silicon; quartz, germanium; and materials of the III-V group having a coefficient of thermal expansion greater than that of silicon, such as GaAs or InP.

As is well known in itself, the principle of molecular bonding, also known as direct bonding, is based on putting two surfaces into direct contact, i.e. without using any specific bonding material (adhesive, wax, solder, etc.). Such an operation requires the surfaces for bonding to be sufficiently smooth, free from particles or contamination, and to be sufficiently close together to enable contact to be initiated, typically at a distance of less than a few nanometers. Under such circumstances, attractive forces between the two surfaces are high enough to cause molecular bonding to occur (bonding induced by all of the attractive forces (Van Der Waals forces) involving electron interaction between atoms or molecules of the two surfaces for bonding together).

Nevertheless, when bonding a sapphire substrate with another substrate having a coefficient of expansion that is different from that of sapphire, the temperature of the reinforcing or stabilizing anneal must be limited (less than 300° C.) in order to avoid cracks appearing and developing in the substrate bonded on the sapphire. Consequently, the bonding surfaces of the two substrates need to be prepared as well as possible for enhancing molecular bonding and obtaining high bonding energy.

As explained above, the sapphire substrate is cleaned after its bonding surface has been polished, which is generally performed by CMP, a polishing or planarizing technique that is well known and that makes use of fabric associated with a polishing solution containing both an agent that is suitable for attacking the surface of the layer chemically (e.g. NH₄OH) and abrasive particles suitable for attacking said surface mechanically (e.g. particles of silica).

The bonding surface of the sapphire substrate is usually subjected to RCA type chemical cleaning which may be followed by scrubbing.

Nevertheless, the Applicant has observed that, even when the sapphire substrate is prepared in that way, the bonding of a silicon substrate on a sapphire substrate can give rise to results that are unsatisfactory, leading in particular to a high density of defects in the silicon, to the formation of a ring (a non-bonded zone at the margins of the wafers) that is wide and irregular, and low bonding energy.

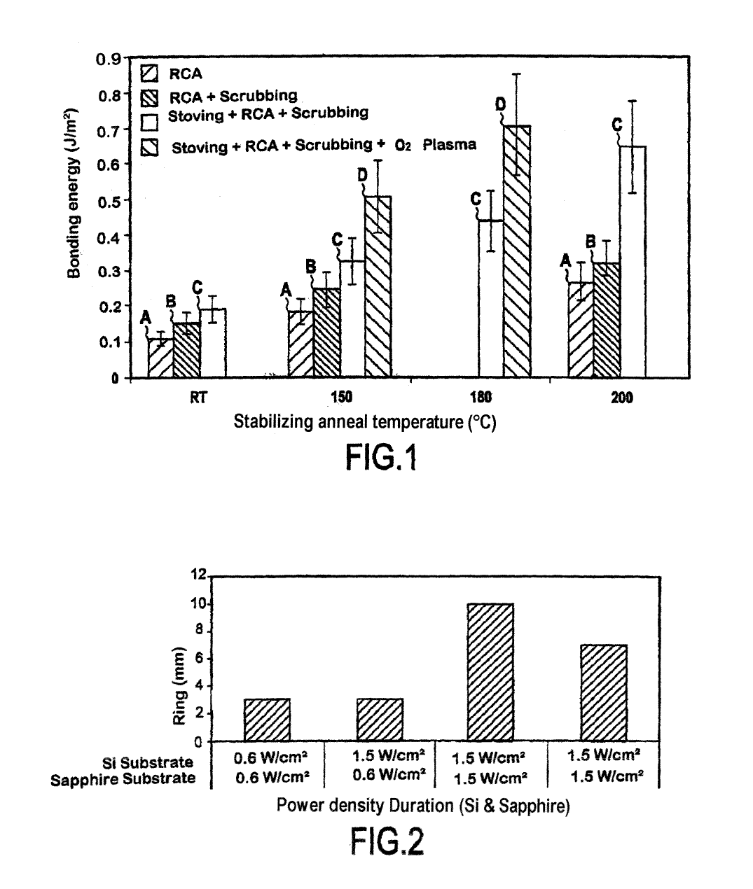

Unexpectedly, the Applicant has found that stoving the sapphire substrate prior to bonding enables the quality of the resulting bonding to be significantly improved compared with bonding performed without such stoving. FIG. 1 shows the bonding energy levels obtained as a function of various different preparations of the bonding surface when fabricating heterostructures of the silicon-on-sapphire (SOS) type. It can be seen that the bonding energy is greater when the sapphire substrate has previously been subjected to stoving at 200° C. for 2 h prior to cleaning and scrubbing (columns C), compared with RCA cleaning on its own (columns A), or with RCA cleaning followed by scrubbing (column B), and that this applies regardless of the stabilizing anneal temperature (lying in the range ambient temperature to 200° C.).

The Applicant has also measured the density of defects (for defects of size lying firstly in the range 100 micrometers (μm) to 500 μm, and secondly in the range 5 μm to 100 μm) on a first SOS type heterostructure for which fabrication included cleaning and scrubbing the sapphire substrate, bonding a silicon substrate on the sapphire substrate, a stabilizing anneal of the bonding, and thinning of the silicon substrate by mechanical polishing (grinding) and chemical etching (TMAH), and on a second SOS type heterostructure for which fabrication included all of the steps used for the first heterostructure together with an additional prior step of stoving the sapphire substrate. The second heterostructure presented a defect density that was ten or more times smaller than the density presented by the first heterostructure. In addition, the second heterostructure presented ring type margin defectuosity (non-transferred peripheral zone as shown in FIG. 2) that was divided by two compared with the first heterostructure.

The step of staving the sapphire substrate in accordance with the invention is performed at a temperature lying in the range 100° C. to 500° C. The duration of the stoving is a function of its temperature. It lies between several minutes and several hours depending on the temperature used. For stoving at the lowest temperature, i.e. 100° C., stoving is performed for a duration of at least 1 h, and preferably over a duration lying in the range 4 h to 5 h. For a temperature of 200° C., the duration of the stoving is about 2 h. At 500° C., the duration of the stoving lies in the range a few minutes to one hour. Consequently, the higher the staving temperature, the shorter its duration.

The stoving is performed in air or in an inert gas such as nitrogen or argon at normal pressure (i.e. atmospheric pressure).

The stoving of the invention serves to eliminate contamination of organic origin in a manner that is much more effective than when using chemical cleaning of the RCA type.

This stoving step also presents the advantage of not modifying the surface state of the sapphire, i.e. of not creating additional atomic steps (“miscut”). Contrary to heat treatment performed at high temperature, stoving in accordance with the invention does not modify the local surface of the sapphire wafer.

According to another aspect of the invention, the quality of the bonding, and in particular the bonding energy, can be further improved by activating the bonding surface(s) of one or both substrates by means of a plasma treatment.

Although activation by plasma treatment is well known for reinforcing bonding energy when performing molecular bonding, the Applicant has determined conditions for such treatment in which optimum bonding energy is obtained while limiting any edge loss type margin defectuosity.

Thus, tests shown in FIG. 2 have shown that the value of the mean power density of the plasma has an influence on the size of the ring (non-bonded zone at the margins of the substrates) and on post-bonding defectuosity. The Applicant has found that in order to obtain good activation of the sapphire bonding surface while avoiding surface degradation that could lead to ring type margin defectuosity (non-transferred peripheral zone), the mean power density of the plasma needs to be limited to about 1 W/cm². This limit on the plasma power density for optimizing bonding is unexpected in that as a general rule the power density of the plasma is not limited to such a value when it is desired to maximize activation of the bonding surfaces.

The bonding surface of the sapphire substrate and/or of the other substrate may be exposed to plasma based on oxygen, nitrogen, argon, etc. Nevertheless, for molecular bonding of a sapphire substrate, it is preferable to use a plasma based on oxygen, since that makes it possible to obtain a bonding energy that is greater and with a density of defects that is smaller in comparison with a plasma based on nitrogen, for example.

The other parameters or conditions for plasma generation are those generally used by the person skilled in the art. By way of example, the plasma based on oxygen may be generated in equipment originally provided for performing reactive ion etching (RIE) with capacitive coupling and under the following conditions:

substrate support chuck connected to a radiofrequency (RE) source at 13.56 megahertz (MHz);

working pressure for the O₂ gas lying in the range 20 millitorr (mTorr) to 100 mTorr;

flow rate of the O₂ gas equal to 75 standard cubic centimeters per minute (sccm); and

plasma exposure time lying in the range 10 seconds (s) to 60 s.

Other equipment using an atmospheric plasma, or indeed provided with an electron cyclotron resonance (ECR) type source or with a Helicon type source can also be used.

The table below shows the roughness and the contact angle measured at the surfaces of sapphire substrates and of silicon substrates.

| | | |
|---|---|---|
| | RMS surface roughness | |
| Surface | (nm) | Contact angle (°) |

| preparation | Al₂O₃ | Si | Al₂O₃ | Si |
|---|---|---|---|---|
| None | 0.18 | ~0.15 | >20 | >10 |
| RCA | 0.18 | 0.12 | 6 | <2 |
| cleaning | | | | |
| RCA | 0.2 | 0.12 | 2 | <2 |
| cleaning + | | | | |
| O₂ plasma | | | | |

It can be seen that when the sapphire substrate has been treated with a plasma based on oxygen, its surface presents a contact angle of 2°. When the sapphire surface has not been treated or has been subjected only to RCA cleaning, the contact angle is respectively greater than 20° or equal to 6°. However, when it is desired to perform hydrophilic molecular bonding, i.e. the type of bonding that is in the most widespread use in silicon-on-insulator (SOI) technology, the bonding surfaces need to present a contact angle of less than 5° in order to have good control over the quality of bonding.

It may also be observed that the oxygen-based plasma treatment of the invention does not significantly increase the roughness of the sapphire surface.

Nevertheless, fabricating a heterostructure of the invention is not restricted to using hydrophilic bonding. The bonding may equally well be hydrophobic.

Furthermore, molecular bonding between the first substrate made of sapphire and the second substrate having a coefficient of thermal expansion different from that of the first substrate is preferably performed at ambient temperature, i.e. at room temperature without using means for heating the substrate during bonding (a temperature generally of about 20° C. and that can vary (±10° C.) depending on the temperature of the room).

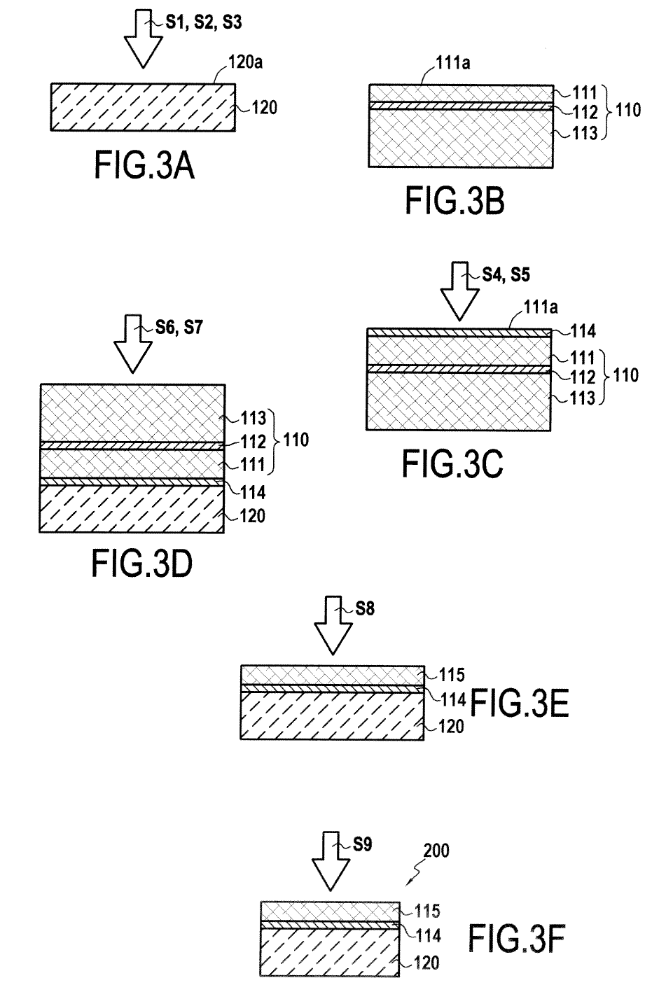

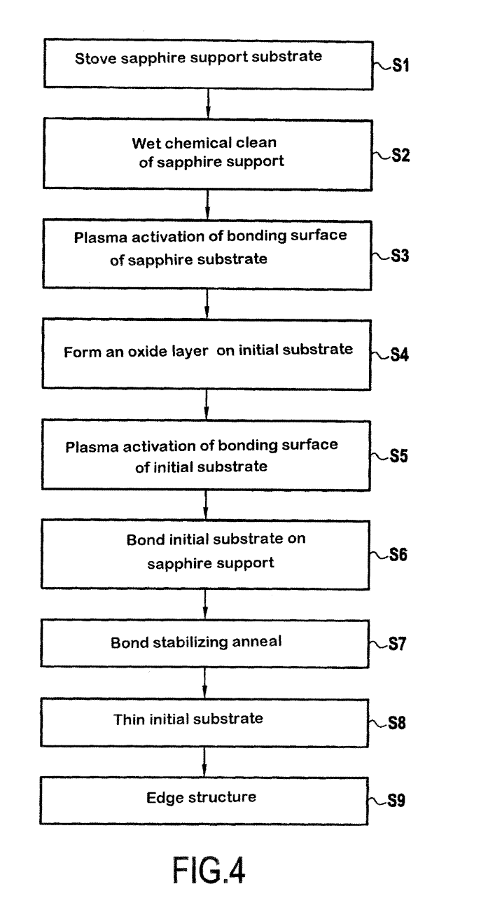

There follows a description with reference to FIGS. 3A to 3F and 4 of a method of fabricating an SOS type heterostructure from a first substrate or initial substrate 110 (Top) and a second substrate or support substrate 120 (Base).

As shown in FIG. 3B, the initial substrate 110 is constituted by an SOI type structure comprising a silicon layer 111 on a support 113 that is also made of silicon, with a buried oxide layer 112, e.g. made of SiO₂, being disposed between the layer 111 and the support 113.

The first substrate or initial substrate may also be constituted by a simple silicon wafer optionally including an oxide layer on its bonding surface.

The support substrate 120 is constituted by a sapphire wafer (FIG. 3A).

Before proceeding with bonding the initial substrate 110 on the support substrate 120, the bonding surface 120a of the sapphire support substrate, which surface has previously been polished, typically by CMP, is itself prepared. In accordance with the invention, the sapphire substrate 120 is subjected to stoving, performed in this example at a temperature of 200° C. for a period of 2 h (step S1). As mentioned above, this staving serves in particular to eliminate contaminants of organic origin present on the bonding surface of the sapphire substrate, thereby enhancing molecular bonding while limiting the appearance of defects.

The bonding surface of the sapphire substrate 120 is then subjected to wet chemical cleaning (step S2). The wet cleaning may be performed in particular by RCA cleaning (i.e. a combination of a bath of SC1 (NH₄OH, H₂O₂, H₂O) suitable for removing particles and hydrocarbons, and a bath of SC2 (HCl, H₂O₂, H₂O) suitable for removing metallic contaminants), cleaning of the “Caro's” or “Piranhaclean” type (H₂SO₄:H₂O₂), or indeed cleaning with an ozone/water (O₃/H₂O) solution.

In order to further decrease the bonding energy, the surface 120a of the substrate 120 can be activated by plasma treatment (step S3). The surface 120a is preferably exposed to an oxygen-based plasma with a mean power density that does not exceed 1 W/cm². The other conditions of the plasma treatment may correspond to those described above.

The surface 111a of the silicon layer 111 of the initial substrate 110 may be covered in a thermal oxide layer 114, e.g. formed by oxidizing the surface of the substrate (FIG. 3C, step S4).

The surface 111a of the initial substrate 110 optionally covered in another oxide layer, may also be activated by plasma treatment (step S5). Since this is a silicon surface, it may be exposed to a standard plasma, i.e. a plasma based on oxygen, nitrogen, argon, etc., with power density that is not limited to 1 W/cm². Activating a silicon bonding surface is well known to the person skilled in the art and is not described in greater detail for reasons of simplification.

One or more cleans subsequent to the plasma exposure may be performed, in particular in order to remove the contaminants that were introduced during exposure, such as rinsing in water and/or cleaning in SC1 (NH₄OH, H₂O₂, H₂O), optionally followed by drying by centrifuging. Nevertheless, these cleans may be replaced by scrubbing that enables a large fraction of the contaminants to be eliminated.

Once they have been prepared, the surfaces 111a and 120a are put into intimate contact and pressure is applied to one of the two substrates so as to initiate the propagation of a bonding wave between the contacting surfaces (step S6, FIG. 3D).

The bonding is then reinforced by performing a bonding reinforcing or stabilizing anneal (step S7). As mentioned above, because of the difference between the coefficients of thermal expansion between sapphire and silicon, the stabilizing anneal is performed at a temperature of less than 300° C. By way of example, the stabilizing anneal may be performed at a temperature of 180° C. for a duration of 2 h.

The fabrication of the heterostructure is continued by thinning the initial substrate 110 so as to form a transferred layer 115 corresponding to a fraction of the silicon layer 111 (step S8, FIG. 3E). Thinning is performed initially by grinding off a major fraction of the support 113 and is then continued by chemical etching, e.g. by means of a solution of tetramethylammonium hydroxide (TMAH).

In an optional step, the structure is edged so as to remove the chamfers and edge roll-off present at the peripheries of the substrates (step S9, FIG. 3F). As shown in FIG. 3F, this gives rise to a heterostructure 200 comprising the sapphire support substrate 120 and the transferred layer 115, with an interposed buried oxide layer 114.

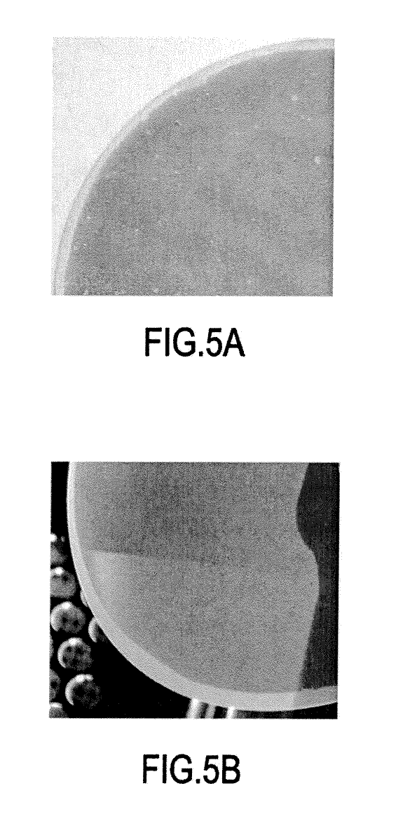

FIG. 5A shows an SOS type heterostructure obtained from an initial SOI substrate bonded on a sapphire support substrate. Prior to bonding, the bonding surface of the sapphire substrate was prepared using RCA cleaning and scrubbing. After bonding, the structure was subjected to a stabilizing anneal at 200° C. for 2 h and it was thinned by grinding and by chemical etching with TMAH.

FIG. 5B also shows an SOS type heterostructure that was made differently from that of FIG. 5A in that prior to the RCA cleaning and the scrubbing, the bonding surface of the sapphire substrate was also prepared by:

stoving at 200° C. for 2 hours;

RCA cleaning (O₃/H₂O, SC1 (NH₄OH, H₂O₂, H₂O), and SC2 (HCl, H₂O₂, H₂O)); and

oxygen-based plasma activation with a mean power density not exceeding 1 W/cm².

In FIG. 5B, it can be seen that practically no defect is visible in the transferred silicon layer, whereas in FIG. 5A, numerous defects are present at the bonding interface and also in the transferred silicon support. These figures thus demonstrate the combined effect of stoving and of surface activation by plasma treatment on reducing the defects present after bonding and a stabilizing anneal.

As explained above, the stoving step of the invention makes it possible to increase the bonding energy in an SOS type structure. This bonding energy may also be increased by activating the bonding surface of the sapphire substrate by plasma treatment as described above. As shown in FIG. 1, it can be seen that the bonding energy is even greater when the surface of the sapphire substrate has been exposed, after stoving, RCA cleaning and scrubbing, to a plasma (column D) as compared with no plasma treatment (column C).

The invention may also be applied to layer transfer techniques other than that described, e.g. in application of the Smart Cut technology.

1. A method of fabricating a heterostructure comprising at least a first substrate made of sapphire and a second substrate made of a material having a coefficient of thermal expansion that is different from that of the first substrate, the method including a step of molecular bonding the second substrate on the first substrate made of sapphire, and prior to bonding the two substrates together, a step of stoving the first substrate that is performed at a temperature lying in the range of 100° C. to 500° C., and when performed at a temperature in the range of 100° C. to 200° C., the duration of the stoving step is at least 1 h.

2. The method according to claim 1, that wherein the staving step is performed at a temperature of about 200° C. over a duration of about 2 h.

3. The method according to claim 1, wherein the stoving step is performed under an atmosphere of air or of inert gas.

4. The method according to claim 1, comprising, after the stoving step, a wet chemical cleaning step.

5. The method according to claim 1, comprising, prior to bonding the two substrates together, a step of activating the bonding surface of the first substrate made of sapphire by plasma treatment, the mean power density of the plasma used being less than or equal to 1 W/cm².

6. The method according to claim 5, wherein the bonding surface of the first substrate made of sapphire is exposed to a plasma based on oxygen.

7. The method according to claim 1, comprising, prior to bonding the two substrates together, forming an oxide layer on the bonding surface of the second substrate.

8. The method according to claim 1, comprising, prior to bonding the two substrates together, a step of activating the bonding surface of the second substrate by plasma treatment.

9. The method according to claim 1, comprising after the two substrates have been bonded together, a step of stabilizing the bonding by annealing at a temperature of less than 300° C.

10. The method according to claim 1, wherein the second substrate is constituted by a layer of silicon.

11. The method according to claim 1, wherein the second substrate is constituted by an SOI structure.

12. The method according to claim 1, wherein the step of molecular bonding the second substrate on the first substrate made of sapphire is performed at ambient temperature.
